(19) United States
(12) Patent Application Publication
(10) Pub. No.: US 2024/0409395 A1
(43) Pub. Date: Dec. 12, 2024

(54) SEMICONDUCTOR DEVICE AND METHOD OF MAKING

(71) Applicant: Taiwan Semiconductor Manufacturing Company Limited, Hsin-Chu (TW)

(72) Inventors: Chih-Chung LEE, Tainan City (TW); Be-Ge Huang, Tainan City (TW); Fei-Lung Lai, New Taipei City (TW); Chuan-Tai Wu, Tainan City (TW)

(21) Appl. No.: 18/206,876

(22) Filed: Jun. 7, 2023

(51) Int. Cl. B81B 7/00; B81C 1/00; G01C 19/00

(52) U.S. Cl. CPC B81B 7/0038; B81C 1/00285; G01C 19/00; B81B 2201/0235; B81B 2201/0242; B81C 2201/013; B81C 2201/0176

(57) ABSTRACT

A semiconductor device is provided. The semiconductor device includes a metal layer. The semiconductor includes a gyroscope including a getter structure overlying the metal layer, wherein the getter structure comprises titanium.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device at a stage of fabrication, in accordance with some embodiments.

FIG. 12 illustrates a cross-sectional view of a semiconductor device, in accordance with some embodiments.

FIG. 13 illustrates a cross-sectional view of a semiconductor device, in accordance with some embodiments.

FIG. 14 illustrates a cross-sectional view of a semiconductor device, in accordance with some embodiments.

FIG. 15 illustrates a cross-sectional view of a semiconductor device, in accordance with some embodiments.

FIG. 16 illustrates a cross-sectional view of a semiconductor device, in accordance with some embodiments.

FIG. 17 illustrates a cross-sectional view of a semiconductor device, in accordance with some embodiments.

FIG. 18 illustrates a cross-sectional view of a semiconductor device, in accordance with some embodiments.

FIG. 19 illustrates a cross-sectional view of a semiconductor device, in accordance with some embodiments.

FIG. 20 illustrates a cross-sectional view of a semiconductor device, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

According to some embodiments, a semiconductor device has a motion sensor including a gyroscope. The gyroscope has a getter structure. The getter structure at least one of reacts with or removes gas in a vacuum sealed space of the gyroscope to promote, maintain, etc. a vacuum in the vacuum sealed space. In accordance with some embodiments, the getter structure comprises titanium. The getter structure comprising titanium provides for a reduction in outgassing in the vacuum sealed space, as compared to getter structures that do not comprise titanium. The reduction in outgassing in the vacuum sealed space improves a stability of the vacuum in the vacuum sealed space, reduces a pressure in the vacuum sealed space, etc., thereby providing for improved performance, stability, etc. of the gyroscope.

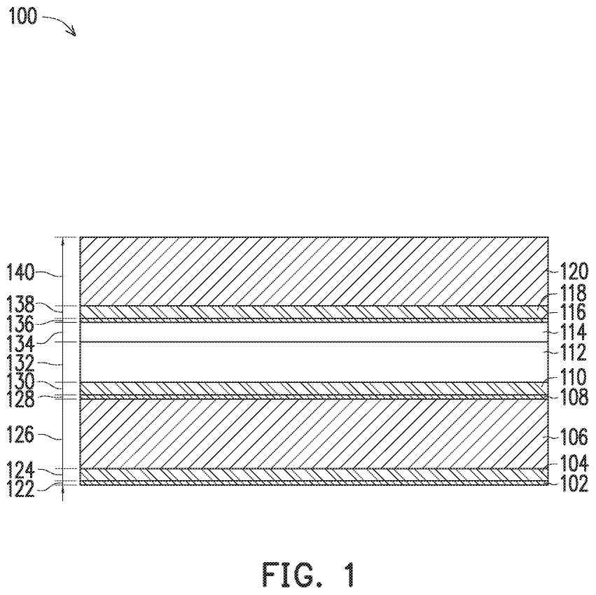

FIGS. 1-19 illustrate cross-sectional views of a semiconductor device 100 at various stages of fabrication, in accordance with some embodiments. In some embodiments, a motion sensor is implemented via the semiconductor device 100. In some embodiments, the motion sensor comprises a microelectromechanical systems (MEMS) motion sensor. The motion sensor comprises at least one of a gyroscope, such as a MEMS gyroscope, or an accelerometer, such as a MEMS accelerometer. The motion sensor is configured for use in measuring one or more parameters, such as at least one of linear acceleration, speed, angular motion, or other parameter. Other structures and/or configurations of the semiconductor device 100 and/or the motion sensor are within the scope of the present disclosure.

FIG. 1 illustrates the semiconductor device 100 according to some embodiments. The semiconductor device 100 comprises at least one of a first metal layer 102, a first metal nitride layer 104, a second metal layer 106, a third metal layer 108, a second metal nitride layer 110, a first oxide layer 112, a second oxide layer 114, a fourth metal layer 116, a third metal nitride layer 118, or a fifth metal layer 120. Other structures and/or configurations of the semiconductor device 100 are within the scope of the present disclosure.

The first metal layer 102 comprises at least one of a metal, a metal alloy, or other suitable material. In some embodiments, the first metal layer 102 comprises at least one of titanium or other suitable metal. In some embodiments, the first metal layer 102 is a titanium-rich layer. A thickness 122 of the first metal layer 102 is between about 50 angstroms to about 200 angstroms, such as about 125 angstroms. Other values of the thickness 122 are within the scope of the present disclosure. The first metal layer 102 is formed by at least one of physical vapor deposition (PVD), sputtering, chemical vapor deposition (CVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques.

The first metal nitride layer 104 comprises at least one of a metal nitride or other suitable material. The first metal nitride layer 104 comprises at least one of titanium nitride or other suitable metal nitride. A thickness 124 of the first metal nitride layer 104 is between about 200 angstroms to about 800 angstroms, such as about 500 angstroms. Other values of the thickness 124 are within the scope of the present disclosure. The first metal nitride layer 104 is formed by at least one of PVD, sputtering, CVD, PECVD, LPCVD, ALCVD, UHVCVD, RPCVD, ALD, MBE, LPE, spin on, growth, or other suitable techniques.

The second metal layer 106 comprises at least one of a metal, a metal alloy, or other suitable material. In some embodiments, the second metal layer 106 comprises at least one of aluminum copper or other suitable metal. A thickness 126 of the second metal layer 106 is between about 2000 angstroms to about 5000 angstroms (such as between about 3000 angstroms to about 4000 angstroms). Other values of the thickness 126 are within the scope of the present disclosure. The second metal layer 106 is formed by at least one of PVD, sputtering, CVD, PECVD, LPCVD, ALCVD, UHVCVD, RPCVD, ALD, MBE, LPE, spin on, growth, or other suitable techniques.

The third metal layer 108 comprises at least one of a metal, a metal alloy, or other suitable material. In some embodiments, the third metal layer 108 comprises at least one of titanium or other suitable metal. In some embodiments, the third metal layer 108 is a titanium-rich layer. A thickness 128 of the third metal layer 108 is between about 50 angstroms to about 200 angstroms, such as about 125 angstroms. Other values of the thickness 128 are within the scope of the present disclosure. The third metal layer 108 is formed by at least one of PVD, sputtering, CVD, PECVD, LPCVD, ALCVD, UHVCVD, RPCVD, ALD, MBE, LPE, spin on, growth, or other suitable techniques. In some embodiments, the third metal layer 108 promotes adhesion between the second metal layer 106 and the second metal nitride layer 110.

The second metal nitride layer 110 comprises at least one of a metal nitride or other suitable material. The second metal nitride layer 110 comprises at least one of titanium nitride or other suitable metal nitride. A thickness 130 of the second metal nitride layer 110 is between about 200 angstroms to about 800 angstroms, such as about 500 angstroms. Other values of the thickness 130 are within the scope of the present disclosure. The second metal nitride layer 110 is formed by at least one of PVD, sputtering, CVD, PECVD, LPCVD, ALCVD, UHVCVD, RPCVD, ALD, MBE, LPE, spin on, growth, or other suitable techniques.

The first oxide layer 112 comprises at least one of an oxide semiconductor material, such as silicon oxide, or other suitable material. In some embodiments, the first oxide layer 112 comprises one or more dopants. In some embodiments, the first oxide layer 112 comprises fluorosilicate glass (FSG). A thickness 132 of the first oxide layer 112 is between about 1000 angstroms to about 10000 angstroms, such as between about 6000 angstroms. Other values of the thickness 132 are within the scope of the present disclosure. In some embodiments, the first oxide layer 112 comprises a first inter-metal dielectric (IMD) layer. The first oxide layer 112 is formed by at least one of PVD, sputtering, CVD, PECVD, LPCVD, ALCVD, UHVCVD, RPCVD, ALD, MBE, LPE, spin on, growth, or other suitable techniques.

The second oxide layer 114 comprises at least one of an oxide semiconductor material, such as silicon oxide, or other suitable material. In some embodiments, the second oxide layer 114 comprises undoped silicate glass (USG). A thickness 134 of the second oxide layer 114 is between about 1000 angstroms to about 10000 angstroms, such as about 5000 angstroms. Other values of the thickness 134 are within the scope of the present disclosure. In some embodiments, the second oxide layer 114 comprises a second IMD layer. The second oxide layer 114 is formed by at least one of PVD, sputtering, CVD, PECVD, LPCVD, ALCVD, UHVCVD, RPCVD, ALD, MBE, LPE, spin on, growth, or other suitable techniques.

The fourth metal layer 116 comprises at least one of a metal, a metal alloy, or other suitable material. In some embodiments, the fourth metal layer 116 comprises at least one of titanium or other suitable metal. In some embodiments, the fourth metal layer 116 is a titanium-rich layer. A thickness 136 of the fourth metal layer 116 is between about 50 angstroms to about 200 angstroms, such as about 125 angstroms. Other values of the thickness 136 are within the scope of the present disclosure. The fourth metal layer 116 is formed by at least one of PVD, sputtering, CVD, PECVD, LPCVD, ALCVD, UHVCVD, RPCVD, ALD, MBE, LPE, spin on, growth, or other suitable techniques. In some embodiments, the fourth metal layer 116 promotes adhesion between the second oxide layer 114 and the third metal nitride layer 118.

The third metal nitride layer 118 comprises at least one of a metal nitride or other suitable material. The third metal nitride layer 118 comprises at least one of titanium nitride or other suitable metal nitride. A thickness 138 of the third metal nitride layer 118 is between about 200 angstroms to about 800 angstroms, such as about 500 angstroms. Other values of the thickness 138 are within the scope of the present disclosure. The third metal nitride layer 118 is formed by at least one of PVD, sputtering, CVD, PECVD, LPCVD, ALCVD, UHVCVD, RPCVD, ALD, MBE, LPE, spin on, growth, or other suitable techniques.

The fifth metal layer 120 comprises at least one of a metal, a metal alloy, or other suitable material. In some embodiments, the fifth metal layer 120 comprises at least one of aluminum copper or other suitable metal. A thickness 140 of the fifth metal layer 120 is between about 2000 angstroms to about 5000 angstroms, such as between about 3000 angstroms to about 4000 angstroms. Other values of the thickness 140 are within the scope of the present disclosure. The fifth metal layer 120 is formed by at least one of PVD, sputtering, CVD, PECVD, LPCVD, ALCVD, UHVCVD, RPCVD, ALD, MBE, LPE, spin on, growth, or other suitable techniques.

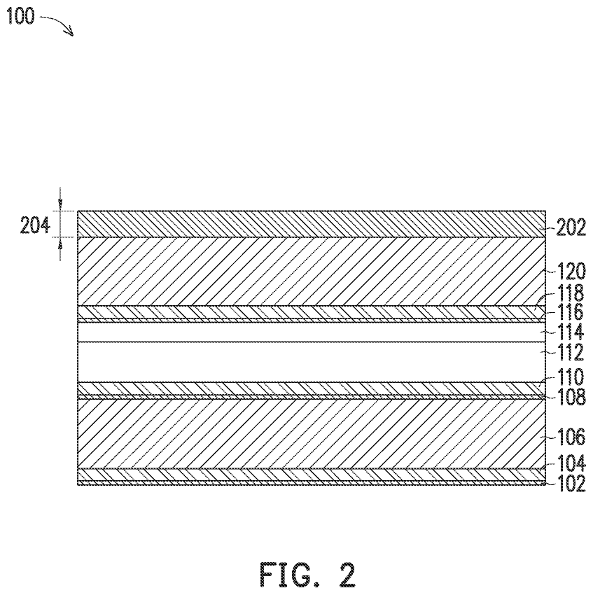

FIG. 2 illustrates a titanium layer 202 formed over the fifth metal layer 120, according to some embodiments. At least some of the titanium layer 202 at least one of overlies the fifth metal layer 120, is in direct contact with the fifth metal layer 120, or is in indirect contact with the fifth metal layer 120. The titanium layer 202 comprises at least one of titanium, a titanium alloy, or other suitable material. In some embodiments, the titanium layer 202 is a titanium-rich layer. A titanium content of the titanium layer 202 is between about 90 weight % of the titanium layer 202 to about 100 weight % of the titanium layer 202 (such as between about 98 weight % of the titanium layer 202 to about 100 weight % of the titanium layer 202). A thickness 204 of the titanium layer 202 is between about 800 angstroms to about 2000 angstroms, such as between about 1200 angstroms. Other values of the thickness 204 and the titanium content of the titanium layer 202 are within the scope of the present disclosure. The titanium layer 202 is formed by at least one of PVD, sputtering, CVD, PECVD, LPCVD, ALCVD, UHVCVD, RPCVD, ALD, MBE, LPE, spin on, growth, or other suitable techniques. In some embodiments, the titanium layer 202 is formed by a PVD sputtering process performed using a sputtering target. In some embodiments, the PVD sputtering process comprises ejecting material from the sputtering target onto the fifth metal layer 120. In some embodiments, the sputtering target comprises titanium. In some embodiments, the sputtering target comprises pure titanium having at least a threshold purity. The threshold purity is between about 99.5% to about 99.9999%. Other values of the threshold purity are within the scope of the present disclosure.

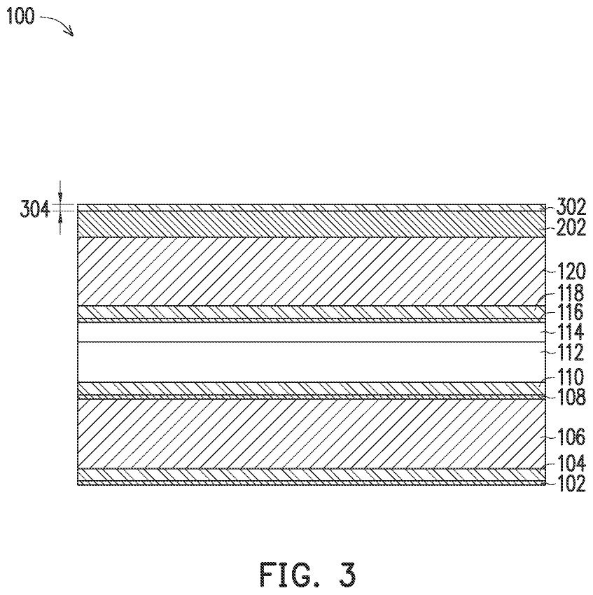

FIG. 3 illustrates a fourth metal nitride layer 302 formed over the titanium layer 202, according to some embodiments. At least some of the fourth metal nitride layer 302 at least one of overlies the titanium layer 202, is in direct contact with the titanium layer 202, or is in indirect contact with the titanium layer 202. The fourth metal nitride layer 302 comprises at least one of titanium nitride or other suitable metal nitride. A thickness 304 of the fourth metal nitride layer 302 is between about 50 angstroms to about 200 angstroms, such as about 100 angstroms. Other values of the thickness 304 are within the scope of the present disclosure. The fourth metal nitride layer 302 is formed by at least one of PVD, sputtering, CVD, PECVD, LPCVD, ALCVD, UHVCVD, RPCVD, ALD, MBE, LPE, spin on, growth, or other suitable techniques.

In some embodiments, the thickness 204 of the titanium layer 202 is larger than the thickness 304 of the fourth metal nitride layer 302. In some embodiments, the thickness 204 of the titanium layer 202 is at least one of (i) over 2 times the thickness 304 of the fourth metal nitride layer 302, (ii) over 5 times the thickness 304 of the fourth metal nitride layer 302, or (iii) over 10 times the thickness 304 of the fourth metal nitride layer 302.

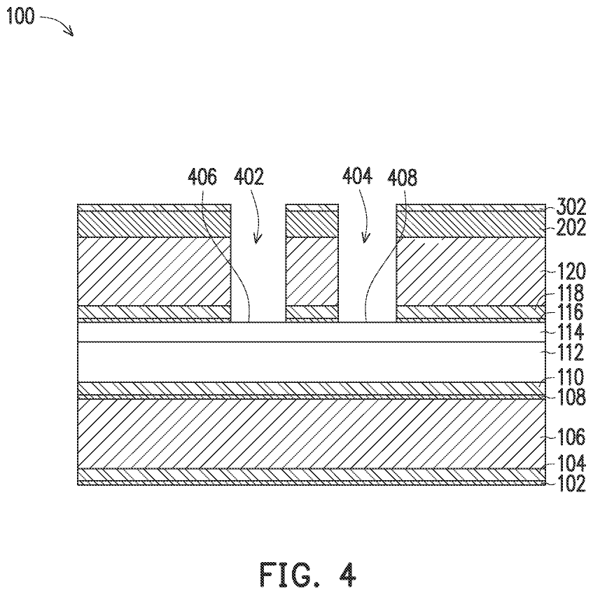

FIG. 4 illustrates a first trench 402 and a second trench 404 formed through one or more layers of the semiconductor device 100, according to some embodiments. In some embodiments, the first trench 402 and/or the second trench 404 extend through at least one of the fourth metal nitride layer 302, the titanium layer 202, the fifth metal layer 120, the third metal nitride layer 118, or the fourth metal layer 116. In some embodiments, forming the first trench 402 exposes a portion 406 of the second oxide layer 114. In some embodiments, forming the second trench 404 exposes a portion 408 of the second oxide layer 114. One or more portions of at least one of the fourth metal nitride layer 302, the titanium layer 202, the fifth metal layer 120, the third metal nitride layer 118, or the fourth metal layer 116 are removed to form the first trench 402 and/or the second trench 404.

According to some embodiments, the first trench 402 and/or the second trench 404 are formed using a first photoresist (not shown). The first photoresist is formed over the fourth metal nitride layer 302 by at least one of PVD, sputtering, CVD, PECVD, LPCVD, ALCVD, UHVCVD, RPCVD, ALD, MBE, LPE, spin on, growth, or other suitable techniques. The first photoresist comprises a light-sensitive material, where properties, such as solubility, of the first photoresist are affected by light. The first photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

In some embodiments, an etching process is performed to remove portions of at least one of the fourth metal nitride layer 302, the titanium layer 202, the fifth metal layer 120, the third metal nitride layer 118, or the fourth metal layer 116 to form the first trench 402 and/or the second trench 404, where one or more openings in the first photoresist allows one or more etchants applied during the etching process to remove portions of at least one of the fourth metal nitride layer 302, the titanium layer 202, the fifth metal layer 120, the third metal nitride layer 118, or the fourth metal layer 116 to form the first trench 402 and/or the second trench 404 while the first photoresist protects or shields portions of the fourth metal nitride layer 302, the titanium layer 202, the fifth metal layer 120, the third metal nitride layer 118, and the fourth metal layer 116 that are covered by the first photoresist. The etching process is at least one of a dry etching process, a wet etching process, an anisotropic etching process, an isotropic etching process, or other suitable etching process. The etching process uses at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material. The first photoresist is stripped or washed away after the first trench 402 and/or the second trench 404 are formed. Other processes and/or techniques for forming the first trench 402 and/or the second trench 404 are within the scope of the present disclosure.

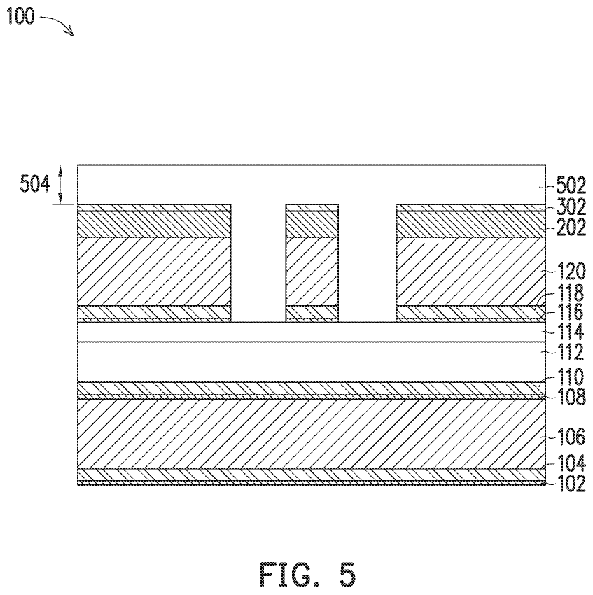

FIG. 5 illustrates a third oxide layer 502 formed at least one of in the first trench 402, in the second trench 404, or over the fourth metal nitride layer 302, according to some embodiments. At least some of the third oxide layer 502 at least one of overlies the fourth metal nitride layer 302, is in direct contact with the fourth metal nitride layer 302, or is in indirect contact with the fourth metal nitride layer 302. In some embodiments, the third oxide layer 502 is deposited into the first trench 402 and/or the second trench 404. The third oxide layer 502 comprises at least one of an oxide semiconductor material, such as silicon oxide, or other suitable material. In some embodiments, the third oxide layer 502 comprises USG. A thickness 504 of the third oxide layer 502 is between about 2000 angstroms to about 6000 angstroms, such as about 4000 angstroms. Other values of the thickness 504 are within the scope of the present disclosure. The third oxide layer 502 is formed by at least one of PVD, sputtering, CVD, PECVD, LPCVD, ALCVD, UHVCVD, RPCVD, ALD, MBE, LPE, spin on, growth, or other suitable techniques. In some embodiments, the third oxide layer 502 is a high density plasma (HDP) layer formed by HDP CVD. In some embodiments, the third oxide layer 502 is a passivation layer.

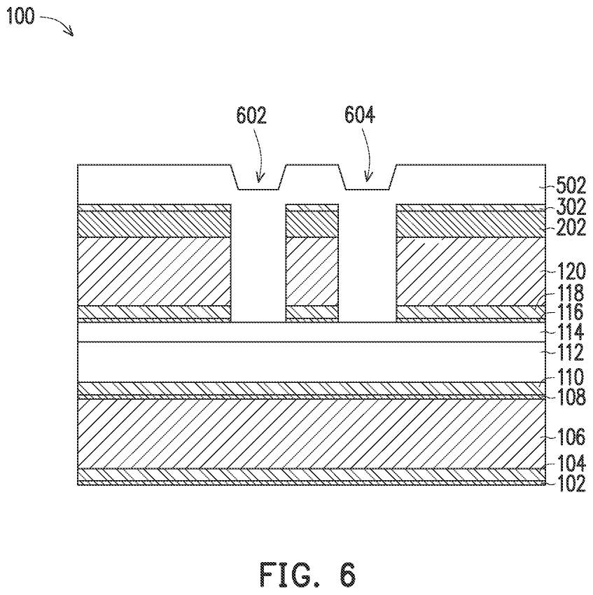

FIG. 6 illustrates a third trench 602 and a fourth trench 604 formed in the third oxide layer 502, according to some embodiments. In some embodiments, the third trench 602 and/or the fourth trench 604 extend through at least a portion of the third oxide layer 502. One or more portions of the third oxide layer 502 are removed to form the third trench 602 and/or the fourth trench 604. According to some embodiments, the third trench 602 and/or the fourth trench 604 are formed using a second photoresist (not shown), such as using one or more of the techniques provided herein with respect to using the first photoresist to form the first trench 402 and/or the second trench 404. In some embodiments, an etching process is performed to remove portions of the third oxide layer 502 to form the third trench 602 and/or the fourth trench 604 using the second photoresist. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. The second photoresist is stripped or washed away after the third trench 602 and/or the fourth trench 604 are formed. Other processes and/or techniques for forming the third trench 602 and/or the fourth trench 604 are within the scope of the present disclosure.

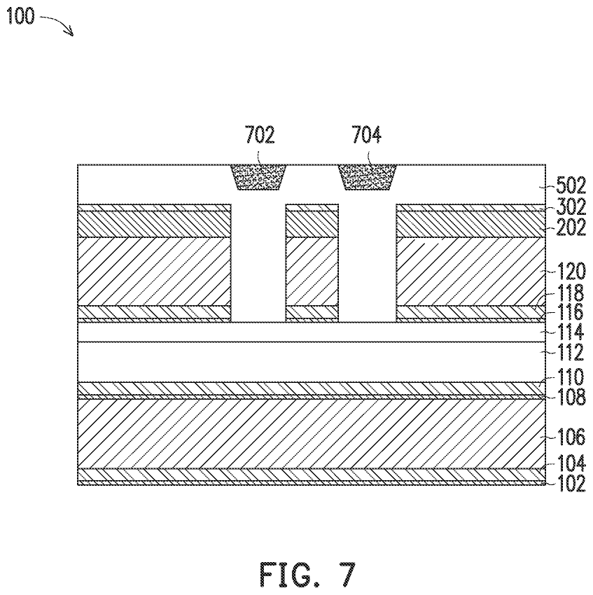

FIG. 7 illustrates a first oxide structure 702 formed in the third trench 602 and a second oxide structure 704 formed in the fourth trench 604, according to some embodiments. The first oxide structure 702 and/or the second oxide structure 704 comprise at least one of an oxide semiconductor material, such as silicon oxide, or other suitable material. The first oxide structure 702 and/or the second oxide structure 704 are formed by at least one of PVD, sputtering, CVD, PECVD, LPCVD, ALCVD, UHVCVD, RPCVD, ALD, MBE, LPE, spin on, growth, or other suitable techniques. In some embodiments, the first oxide structure 702 and/or the second oxide structure 704 are physical enhanced oxidation (PEOX) structures formed by performing a PEOX process. According to some embodiments, a top surface of the first oxide structure 702 and/or a top surface of the second oxide structure 704 are level or coplanar with a top surface of the third oxide layer 502. In some embodiments, a material, such as an oxide semiconductor material, is deposited into the third trench 602 and the fourth trench 604 to form the first oxide structure 702 and the second oxide structure 704. In some embodiments, after depositing the material, a top portion of the material is removed by at least one of chemical-mechanical polishing (CMP), etching, or other suitable techniques. The top portion of the material is removed such that the top surface of the first oxide structure 702 and/or the top surface of the second oxide structure 704 are level or coplanar with the top surface of the third oxide layer 502. Other structures and/or configurations of the first oxide structure 702 and/or the second oxide structure 704 relative to other elements, features, etc. are within the scope of the present disclosure.

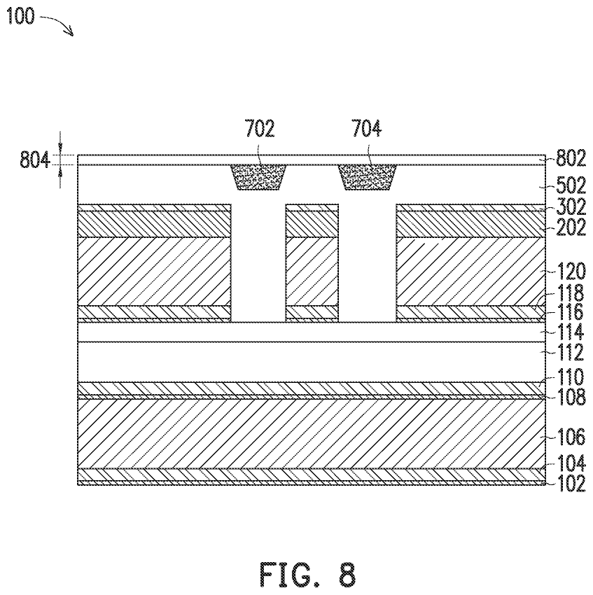

FIG. 8 illustrates a fourth oxide layer 802 formed over the third oxide layer 502, according to some embodiments. At least some of the fourth oxide layer 802 at least one of overlies the third oxide layer 502, is in direct contact with the third oxide layer 502, or is in indirect contact with the third oxide layer 502. The fourth oxide layer 802 comprises at least one of an oxide semiconductor material, such as silicon oxide, or other suitable material. A thickness 804 of the fourth oxide layer 802 is between about 1000 angstroms to about 2000 angstroms, such as about 1500 angstroms. Other values of the thickness 804 are within the scope of the present disclosure. The fourth oxide layer 802 is formed by at least one of PVD, sputtering, CVD, PECVD, LPCVD, ALCVD, UHVCVD, RPCVD, ALD, MBE, LPE, spin on, growth, or other suitable techniques. In some embodiments, the fourth oxide layer 802 is at least one of a silicon rich oxide (SRO) layer or a passivation layer.

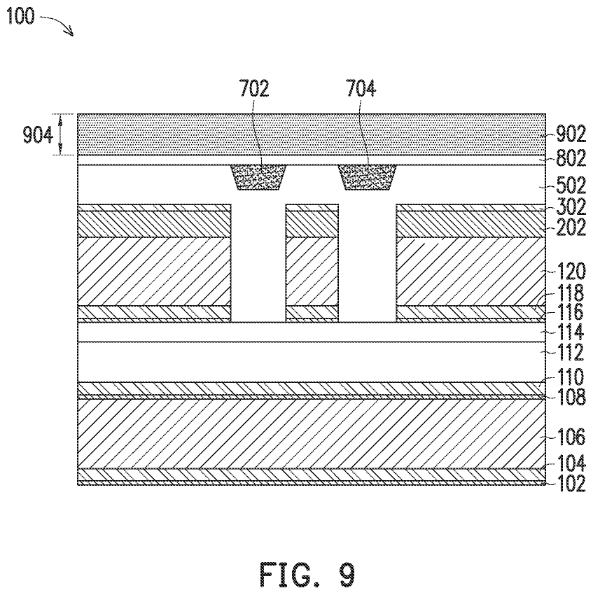

FIG. 9 illustrates a nitride layer 902 formed over the fourth oxide layer 802, according to some embodiments. At least some of the nitride layer 902 at least one of overlies the fourth oxide layer 802, is in direct contact with the fourth oxide layer 802, or is in indirect contact with the fourth oxide layer 802. The nitride layer 902 comprises at least one of a nitride semiconductor material, such as silicon nitride, or other suitable material. A thickness 904 of the nitride layer 902 is between about 2000 angstroms to about 6000 angstroms, such as about 4000 angstroms. Other values of the thickness 904 are within the scope of the present disclosure. The nitride layer 902 is formed by at least one of PVD, sputtering, CVD, PECVD, LPCVD, ALCVD, UHVCVD, RPCVD, ALD, MBE, LPE, spin on, growth, or other suitable techniques. In some embodiments, the nitride layer 902 is a passivation layer.

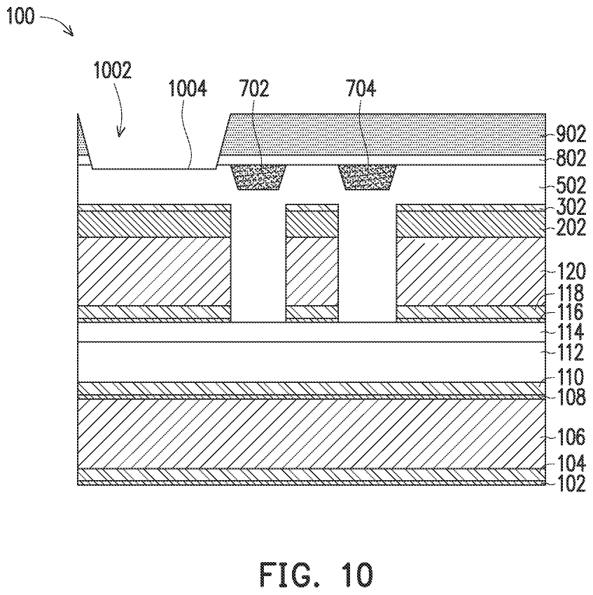

FIG. 10 illustrates a fifth trench 1002 formed through one or more layers of the semiconductor device 100, according to some embodiments. In some embodiments, the fifth trench 1002 extends through at least one of the nitride layer 902, the fourth oxide layer 802, or the third oxide layer 502. In some embodiments, forming the fifth trench 1002 exposes a portion 1004 of the third oxide layer 502. One or more portions of at least one of the nitride layer 902, the fourth oxide layer 802, or the third oxide layer 502 are removed to form the fifth trench 1002. According to some embodiments, the fifth trench 1002 is formed using a third photoresist (not shown), such as using one or more of the techniques provided herein with respect to using the first photoresist to form the first trench 402 and/or the second trench 404. In some embodiments, an etching process is performed to remove portions of at least one of the nitride layer 902, the fourth oxide layer 802, or the third oxide layer 502 to form the fifth trench 1002 using the third photoresist. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. The third photoresist is stripped or washed away after the fifth trench 1002 is formed. Other processes and/or techniques for forming the fifth trench 1002 are within the scope of the present disclosure.

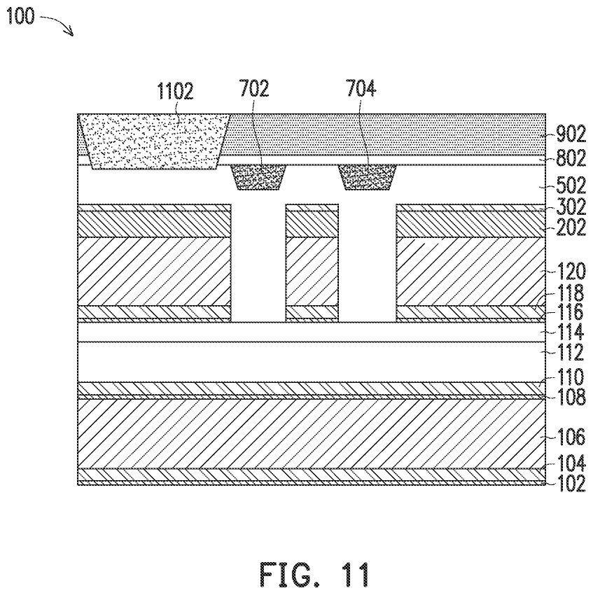

FIG. 11 illustrates a third oxide structure 1102 formed in the fifth trench 1002, according to some embodiments. The third oxide structure 1102 comprises at least one of an oxide semiconductor material, such as silicon oxide, or other suitable material. The third oxide structure 1102 is formed by at least one of PVD, sputtering, CVD, PECVD, LPCVD, ALCVD, UHVCVD, RPCVD, ALD, MBE, LPE, spin on, growth, or other suitable techniques. According to some embodiments, a top surface of the third oxide structure 1102 is level or coplanar with a top surface of the nitride layer 902. In some embodiments, a material, such as an oxide semiconductor material, is deposited into the fifth trench 1002 to form the third oxide structure 1102. In some embodiments, after depositing the material, a top portion of the material is removed by at least one of CMP, etching, or other suitable techniques. The top portion of the material is removed such that the top surface of the third oxide structure 1102 is level or coplanar with the top surface of the nitride layer 902. In some embodiments, the third oxide structure 1102 is a HDP structure formed by HDP CVD. Other structures and/or configurations of the third oxide structure 1102 relative to other elements, features, etc. are within the scope of the present disclosure.

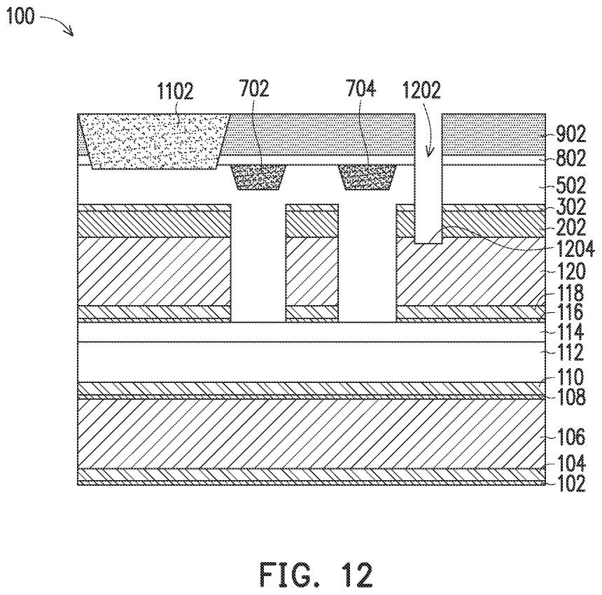

FIG. 12 illustrates a sixth trench 1202 formed through one or more layers of the semiconductor device 100, according to some embodiments. In some embodiments, the sixth trench 1202 extends through at least one of the nitride layer 902, the fourth oxide layer 802, the third oxide layer 502, the fourth metal nitride layer 302, the titanium layer 202, or the fifth metal layer 120. In some embodiments, forming the sixth trench 1202 exposes a portion 1204 of the fifth metal layer 120. One or more portions of at least one of the nitride layer 902, the fourth oxide layer 802, the third oxide layer 502, the fourth metal nitride layer 302, the titanium layer 202, or the fifth metal layer 120 are removed to form the sixth trench 1202. According to some embodiments, the sixth trench 1202 is formed using a fourth photoresist (not shown), such as using one or more of the techniques provided herein with respect to using the first photoresist to form the first trench 402 and/or the second trench 404. In some embodiments, an etching process is performed to remove portions of at least one of the nitride layer 902, the fourth oxide layer 802, the third oxide layer 502, the fourth metal nitride layer 302, the titanium layer 202, or the fifth metal layer 120 to form the sixth trench 1202 using the fourth photoresist. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. The fourth photoresist is stripped or washed away after the sixth trench 1202 is formed. Other processes and/or techniques for forming the sixth trench 1202 are within the scope of the present disclosure.

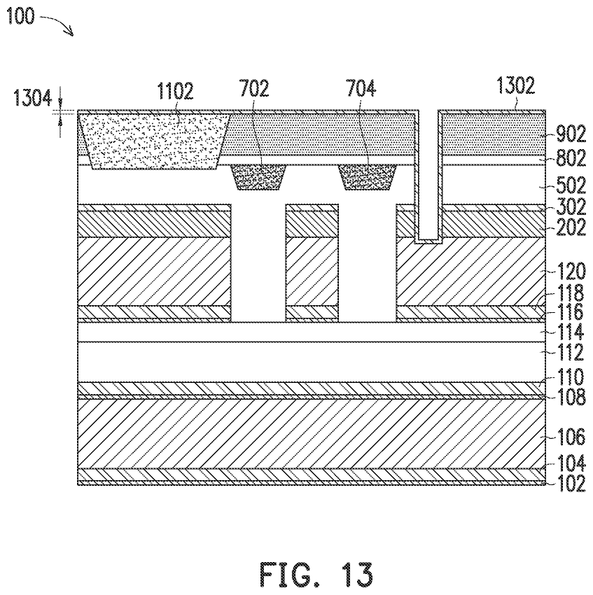

FIG. 13 illustrates a fifth metal nitride layer 1302 formed at least one of in the sixth trench 1202 or over the nitride layer 902, according to some embodiments. At least some of the fifth metal nitride layer 1302 at least one of overlies the nitride layer 902, is in direct contact with the nitride layer 902, or is in indirect contact with the nitride layer 902. The fifth metal nitride layer 1302 comprises at least one of titanium nitride or other suitable metal nitride. A thickness 1304 of the fifth metal nitride layer 1302 is between about 200 angstroms to about 800 angstroms (such as about 500 angstroms). Other values of the thickness 1304 are within the scope of the present disclosure. The fifth metal nitride layer 1302 is formed by at least one of PVD, sputtering, CVD, PECVD, LPCVD, ALCVD, UHVCVD, RPCVD, ALD, MBE, LPE, spin on, growth, or other suitable techniques.

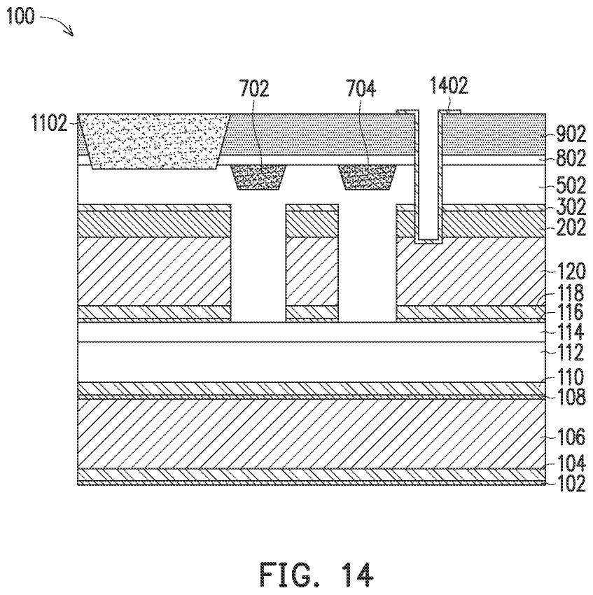

FIG. 14 illustrates the fifth metal nitride layer 1302 patterned to form a patterned metal nitride layer 1402, according to some embodiments. In some embodiments, one or more portions of the fifth metal nitride layer 1302 that are outside of the sixth trench 1202 are removed to form the patterned metal nitride layer 1402. According to some embodiments, the patterned metal nitride layer 1402 is formed using a fifth photoresist (not shown), such as using one or more of the techniques provided herein with respect to using the first photoresist to form the first trench 402 and/or the second trench 404. In some embodiments, an etching process is performed to remove the one or more portions of the fifth metal nitride layer 1302 using the fifth photoresist. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. The fifth photoresist is stripped or washed away after the one or more portions of the fifth metal nitride layer 1302 are removed to form the patterned metal nitride layer 1402. Other processes and/or techniques for forming the patterned metal nitride layer 1402 are within the scope of the present disclosure.

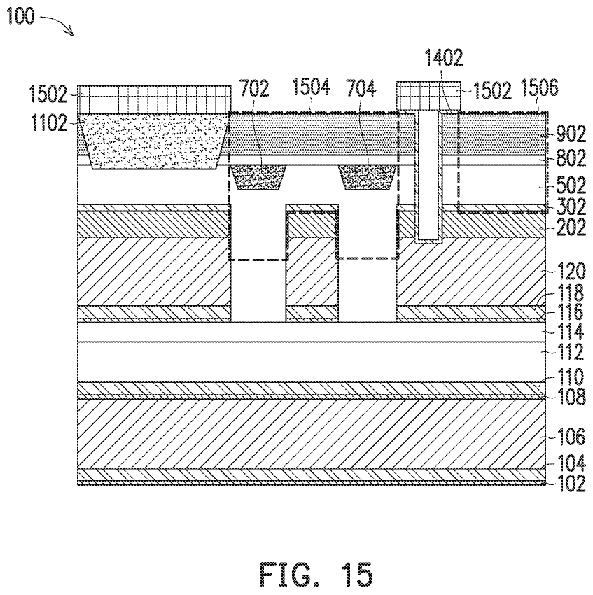

FIG. 15 illustrates a first patterned mask layer 1502 formed over the nitride layer 902, according to some embodiments. In some embodiments, a first mask layer (not shown) is formed over the nitride layer 902, and is patterned to form the first patterned mask layer 1502. In some embodiments, the first mask layer is a hard mask layer. The first mask layer comprises at least one of oxide, nitride, a metal, or other suitable material. The first mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the first patterned mask layer 1502 comprises at least one of a first portion overlying the third oxide structure 1102 or a second portion overlying the patterned metal nitride layer 1402.

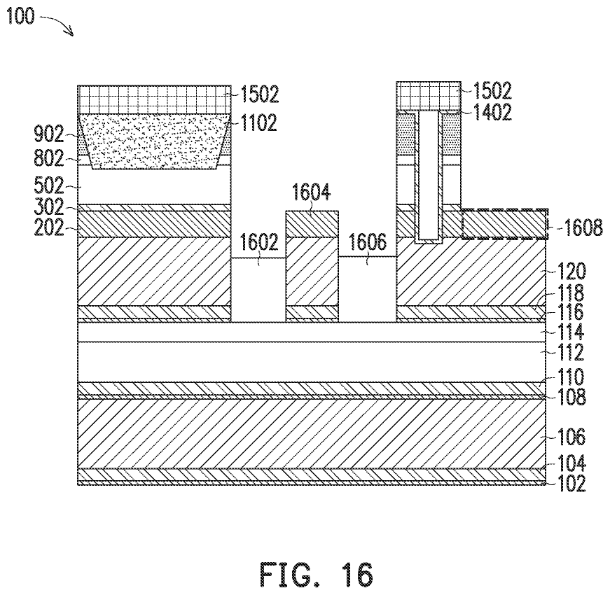

FIG. 16 illustrates use of the first patterned mask layer 1502 to remove one or more first portions of the semiconductor device 100, according to some embodiments. In some embodiments, the one or more first portions of the semiconductor device 100 comprise at least one of the first oxide structure 702, the second oxide structure 704, one or more portions of the fourth metal nitride layer 302, one or more portions of the third oxide layer 502, one or more portions of the fourth oxide layer 802, or one or more portions of the nitride layer 902. FIG. 15 shows a dashed-line outline 1504 and a dashed-line outline 1506 of the one or more first portions of the semiconductor device 100 that are removed, according to some embodiments. In some embodiments, an etching process is performed to remove the one or more first portions of the semiconductor device 100, where openings in the first patterned mask layer 1502 allow one or more etchants applied during the etching process to remove the one or more first portions of the semiconductor device 100 while the first patterned mask layer 1502 protects or shields portions of the semiconductor device 100 that are covered by the first patterned mask layer 1502. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. Other processes and/or techniques for removing the one or more first portions of the semiconductor device 100 are within the scope of the present disclosure. Referring to FIG. 16, according to some embodiments, removal of the one or more first portions of the semiconductor device 100 exposes at least one of a portion 1602 of the third oxide layer 502, a portion 1604 of the titanium layer 202, a portion 1606 of the third oxide layer 502, or a portion 1608, of the titanium layer 202, corresponding to a getter structure of the gyroscope of the semiconductor device 100. The first patterned mask layer 1502 is removed after the removal of the one or more first portions of the semiconductor device 100.

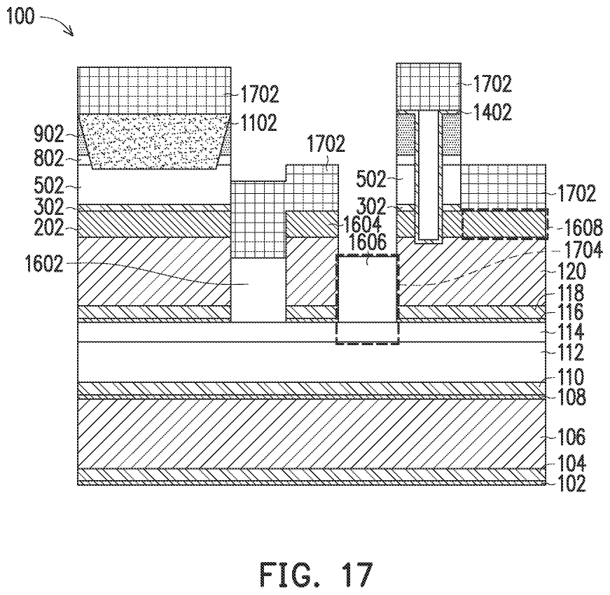

FIG. 17 illustrates a second patterned mask layer 1702 formed over the semiconductor device 100, according to some embodiments. In some embodiments, a second mask layer (not shown) is formed over the nitride layer 902, and is patterned to form the second patterned mask layer 1702. In some embodiments, the second mask layer is a hard mask layer. The second mask layer comprises at least one of oxide, nitride, a metal, or other suitable material. The second mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the second patterned mask layer 1702 comprises at least one of a first portion overlying the third oxide structure 1102, a second portion overlying the portion 1602 of the third oxide layer 502, a third portion overlying the portion 1604 of the titanium layer 202, a fourth portion overlying the patterned metal nitride layer 1402, or a fifth portion overlying the portion 1608, of the titanium layer 202, corresponding to the getter structure of the gyroscope of the semiconductor device 100.

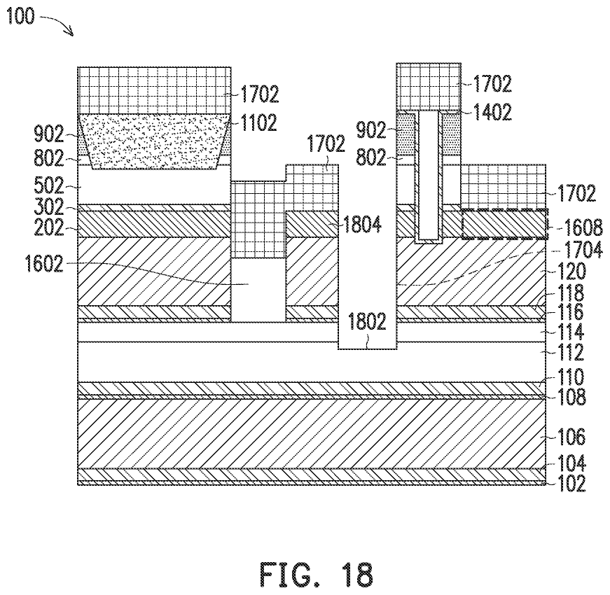

FIG. 18 illustrates use of the second patterned mask layer 1702 to remove one or more second portions of the semiconductor device 100, according to some embodiments. In some embodiments, the one or more second portions of the semiconductor device 100 comprise at least one of the portion 1606 of the third oxide layer 502, a portion of the second oxide layer 114 underlying the portion 1606 of the third oxide layer 502, or a portion of the first oxide layer 112 underlying the portion 1606 of the third oxide layer 502. FIG. 17 shows a dashed-line outline 1704 of the one or more second portions of the semiconductor device 100 that are removed, according to some embodiments. In some embodiments, an etching process is performed to remove the one or more second portions of the semiconductor device 100, where one or more openings in the second patterned mask layer 1702 allow one or more etchants applied during the etching process to remove the one or more second portions of the semiconductor device 100 while the second patterned mask layer 1702 protects or shields portions of the semiconductor device 100 that are covered by the second patterned mask layer 1702. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. Other processes and/or techniques for removing the one or more second portions of the semiconductor device 100 are within the scope of the present disclosure. Referring to FIG. 18, according to some embodiments, removal of the one or more second portions of the semiconductor device 100 exposes a portion 1802 of the first oxide layer 112. The second patterned mask layer 1702 is removed after the removal of the one or more second portions of the semiconductor device 100.

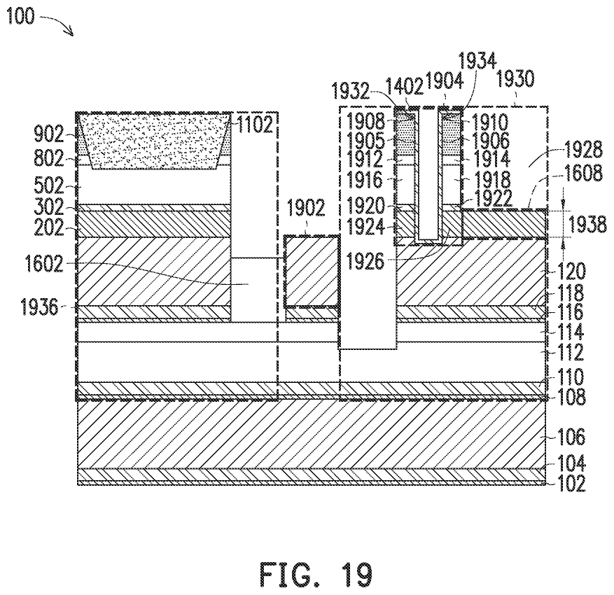

FIG. 19 illustrates removing a portion 1804 (shown in FIG. 19) of the titanium layer 202, according to some embodiments. In some embodiments, the portion 1804 of the titanium layer 202 is removed to expose a portion 1902 of the fifth metal layer 120. In some embodiments, the portion 1902 of the fifth metal layer 120 corresponds to a bump pad of the semiconductor device 100. In some embodiments, the bump pad is used to connect at least one of a connection element, an interconnect structure, a contact, a via, a metal line, etc. of the semiconductor device 100 to a second semiconductor device (not shown). In some embodiments, the bump pad is soldered to the second semiconductor device, such as to a second bump pad on the second semiconductor device. In some embodiments, an etching process is performed to remove the portion 1804 of the titanium layer 202. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. In some embodiments, the etching process is performed using at least one of a sixth photoresist (such as using one or more of the techniques provided herein with respect to the first photoresist) or a third mask layer (such as using one or more of the techniques provided herein with respect to the first patterned mask layer 1502 and/or the second patterned mask layer 1702). Other processes and/or techniques for removing the portion 1804 of the titanium layer 202 are within the scope of the present disclosure.

In some embodiments, at least a portion of the gyroscope of the semiconductor device 100 is in a dashed-line outline 1930 shown in FIG. 19. In some embodiments, the getter structure comprising the portion 1608 of the titanium layer 202 is exposed to a vacuum sealed space 1928 defined by one or more walls and/or sealants (not shown) of the semiconductor device 100. In some embodiments, the getter structure at least one of reacts with or removes gas in the vacuum sealed space 1928 to at least one of promote, maintain, etc. a vacuum in the vacuum sealed space 1928. In some embodiments, using the portion 1608 of the titanium layer 202 as the getter structure provides for a reduction, such as at least about a 5% reduction, in outgassing in the vacuum sealed space 1028, as compared to some systems that use getter structures without titanium. In some embodiments, the reduction in outgassing in the vacuum sealed space 1028 at least one of improves a stability of the vacuum in the vacuum sealed space 1928, reduces a pressure in the vacuum sealed space 1928, etc., thereby providing for improved performance, stability, etc. of the gyroscope. A thickness 1938 of the getter structure is at least about 800 angstroms, such as between about 800 angstroms to about 2000 angstroms. In some embodiments, the thickness 1938 of the getter structure corresponds to the thickness 204 (shown in FIG. 2) of the titanium layer 202. In some embodiments, as compared to using some getter structures that have thicknesses smaller than 800 angstroms, using the getter structure having the thickness 1938 of at least about 800 angstroms provides for at least one of an improvement to the stability of the vacuum in the vacuum sealed space 1928, a reduction to the pressure in the vacuum sealed space 1928, etc., thereby providing for improved performance, stability, etc. of the gyroscope. Other values of the thickness 1938 are within the scope of the present disclosure.

In some embodiments, the gyroscope comprises a bump stop structure 1904. In some embodiments, the bump stop structure is used to control, limit, etc. movement of at least one of the gyroscope, the semiconductor device 100, the motion sensor, or the accelerometer. In some embodiments, the bump stop structure comprises a first dielectric structure and a second dielectric structure. The first dielectric structure comprises at least one of a structure 1908 comprising a portion of the nitride layer 902, a structure 1912 comprising a portion of the fourth oxide layer 802, a structure 1916 comprising a portion of the third oxide layer 502, a structure 1920 comprising a portion of the fourth metal nitride layer 302, or a structure 1924 comprising a portion of the titanium layer 202. The second dielectric structure comprises at least one of a structure 1910 comprising a portion of the nitride layer 902, a structure 1914 comprising a portion of the fourth oxide layer 802, a structure 1918 comprising a portion of the third oxide layer 502, a structure 1922 comprising a portion of the fourth metal nitride layer 302, or a structure 1926 comprising a portion of the titanium layer 202. A sidewall 1932 of the first dielectric structure faces and is spaced apart from a sidewall 1934 of the second dielectric structure. In some embodiments, the sidewall 1932 of the first dielectric structure is made up of sidewalls of at least one of the structure 1908, the structure 1912, the structure 1916, the structure 1920, or the structure 1924. In some embodiments, the sidewall 1934 of the second dielectric structure is made up of sidewalls of at least one of the structure 1910, the structure 1914, the structure 1918, the structure 1922, or the structure 1926. The patterned metal nitride layer 1402 comprises a first portion 1905 aligned with the sidewall 1932 of the first dielectric structure and a second portion 1906 aligned with the sidewall 1934 of the second dielectric structure. The first portion 1905 of the patterned metal nitride layer 1402 is spaced apart from the second portion 1906 of the patterned metal nitride layer 1402. Other structures and/or configurations of the bump stop structure 1904 relative to other elements, features, etc. are within the scope of the present disclosure.

In some embodiments, at least a portion of the accelerometer of the semiconductor device 100 is in a dashed-line outline 1936 shown in FIG. 19. In some embodiments, the third oxide structure 1102 corresponds to an outgassing structure of the accelerometer. In some embodiments, the third oxide structure 1102 is a source of outgas, and contributes to an increased pressure in the accelerometer, as compared to the pressure in the vacuum sealed space 1928 of the gyroscope. In some embodiments, the increased pressure in the accelerometer provides for increased stability, reduced noise, etc. of the accelerometer.

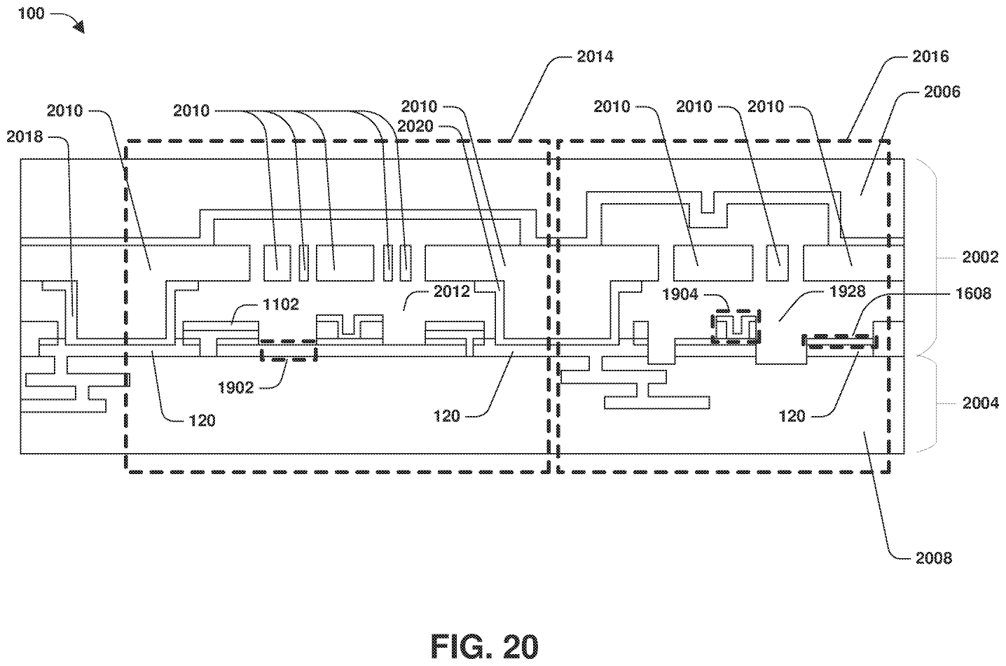

FIG. 20 illustrates a cross-sectional view of the semiconductor device 100 according to some embodiments. In some embodiments, the semiconductor device 100 comprises a first portion 2002 and a second portion 2004. In some embodiments, the first portion 2002 overlies the second portion 2004. In some embodiments, the first portion 2002 comprises a MEMS structure. In some embodiments, the second portion 2004 comprises a complementary metal-oxide semiconductor (CMOS) structure. In some embodiments, the first portion 2002 comprises a first semiconductor layer 2006. In some embodiments, the second portion 2004 comprises a second semiconductor layer 2008.

In some embodiments, the first semiconductor layer 2006 comprises a first semiconductor substrate. The first semiconductor layer 2006 comprises at least one of an epitaxial layer, a silicon-on-insulator (SOI) structure, a wafer, or a die formed from a wafer. The first semiconductor layer 2006 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP or other suitable material. In some embodiments, the first semiconductor layer 2006 comprises at least one of monocrystalline silicon, crystalline silicon with a <100> crystallographic orientation, crystalline silicon with a <110> crystallographic orientation, crystalline silicon with a <111> crystallographic orientation or other suitable material. In some embodiments, the first semiconductor layer 2006 has at least one doped region. Other structures and/or configurations of the first semiconductor layer 2006 are within the scope of the present disclosure. Embodiments are contemplated in which the first semiconductor layer 2006 comprises a material, such as at least one of a metal, a metal alloy, or other suitable material, different than a semiconductor material.

In some embodiments, the second semiconductor layer 2008 comprises a second semiconductor substrate. The second semiconductor layer 2008 comprises at least one of an epitaxial layer, a SOI structure, a wafer, or a die formed from a wafer. The second semiconductor layer 2008 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP or other suitable material. In some embodiments, the second semiconductor layer 2008 comprises at least one of monocrystalline silicon, crystalline silicon with a <100> crystallographic orientation, crystalline silicon with a <110> crystallographic orientation, crystalline silicon with a <111> crystallographic orientation or other suitable material. In some embodiments, the second semiconductor layer 2008 has at least one doped region. Other structures and/or configurations of the second semiconductor layer 2008 are within the scope of the present disclosure. Embodiments are contemplated in which the second semiconductor layer 2008 comprises a material, such as at least one of a metal, a metal alloy, or other suitable material, different than a semiconductor material. In some embodiments, at least one of the first metal layer 102, the first metal nitride layer 104, the second metal layer 106, the third metal layer 108, the second metal nitride layer 110, the first oxide layer 112, the second oxide layer 114, the fourth metal layer 116, the third metal nitride layer 118, the fifth metal layer 120, the titanium layer 202, the portion 1902 of the fifth metal layer 120, the third oxide structure 1102, the bump stop structure 1904, or the getter structure comprising the portion 1608 of the titanium layer 202 overlie the second semiconductor layer 2008.

In some embodiments, the semiconductor device 100 comprises one or more structures 2010 between the first semiconductor layer 2006 and the second semiconductor layer 2008. In some embodiments, a structure of the one or more structures 2010 comprises at least one of a nitride semiconductor material, such as silicon nitride, a metal, a metal alloy, or other suitable material. In some embodiments, a structure of the one or more structures 2010 comprises at least one of titanium, aluminum copper, or other suitable metal. In some embodiments, the semiconductor device 100 comprises a layer 2018 between the fifth metal layer 120 and a structure of the one or more structures 2010. In some embodiments, the layer 2018 comprises at least one of a nitride semiconductor material, such as silicon nitride, a metal, a metal alloy, or other suitable material. In some embodiments, the layer 2018 comprises at least one of titanium, aluminum copper, or other suitable metal. In some embodiments, the semiconductor device 100 comprises a layer 2020 between the fifth metal layer 120 and a structure of the one or more structures 2010. In some embodiments, the layer 2020 comprises at least one of a nitride semiconductor material, such as silicon nitride, a metal, a metal alloy, or other suitable material. In some embodiments, the layer 2020 comprises at least one of titanium, aluminum copper, or other suitable metal.

In some embodiments, the accelerometer of the semiconductor device 100 is implemented via a portion, of the semiconductor device 100, within a dashed-line outline 2014 shown in FIG. 20. In some embodiments, the gyroscope of the semiconductor device 100 is implemented via a portion, of the semiconductor device 100, within a dashed-line outline 2016 shown in FIG. 20. In some embodiments, the getter structure comprising the portion 1608 of the titanium layer 202 is exposed to the vacuum sealed space 1928 of the gyroscope. In some embodiments, the vacuum sealed space 1928 is isolated from an external environment, such as an area outside or inside the semiconductor device 100, by at least one of the one or more structures 2010, the layer 2020, the first semiconductor layer 2020, or one or more other structures. In some embodiments, the vacuum sealed space 1928 is isolated from a space 2012 of the accelerometer by at least one of the one or more structures 2010, the layer 2020, the first semiconductor layer 2020, or one or more other structures. In some embodiments, the getter structure at least one of reacts with or removes gas in the vacuum sealed space 1928 to at least one of promote, maintain, etc. a vacuum in the vacuum sealed space 1928.

In some embodiments, a semiconductor device is provided. The semiconductor device includes a metal layer. The semiconductor includes a gyroscope including a getter structure overlying the metal layer, wherein the getter structure comprises titanium.

In some embodiments, a semiconductor device is provided. The semiconductor device includes a metal layer. The semiconductor includes a gyroscope including a getter structure overlying the metal layer, wherein the getter structure comprises titanium. The semiconductor includes an accelerometer comprising an outgassing structure overlying the metal layer.

In some embodiments, a method for forming a semiconductor device is provided. The method includes forming a titanium layer over a metal layer. The method includes forming a metal nitride layer over the titanium layer. The method includes forming one or more dielectric layers over the metal nitride layer. The method includes removing a portion of the one or more dielectric layers and a portion of the metal nitride layer to expose a portion, of the titanium layer, corresponding to a getter structure of a gyroscope.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
a metal layer; and
a gyroscope comprising a getter structure overlying the metal layer, wherein the getter structure comprises titanium.

2. The semiconductor device of claim 1, wherein:
the getter structure is exposed to a vacuum sealed space.

3. The semiconductor device of claim 1, wherein:
the gyroscope comprises a bump stop structure overlying the metal layer.

4. The semiconductor device of claim 3, wherein the bump stop structure comprises:
a first dielectric structure;
a second dielectric structure, wherein a sidewall of the first dielectric structure faces and is spaced apart from a sidewall of the second dielectric structure; and
a metal nitride layer comprising:
a first portion aligned with the sidewall of the first dielectric structure; and
a second portion aligned with the sidewall of the second dielectric structure.

5. The semiconductor device of claim 4, wherein:
the first portion of the metal nitride layer is spaced apart from the second portion of the metal nitride layer.

6. The semiconductor device of claim 4, wherein:
the metal nitride layer comprises titanium nitride.

7. The semiconductor device of claim 4, wherein:
the first dielectric structure comprises:
a first oxide structure; and
a first nitride structure overlying the first oxide structure;
the second dielectric structure comprises:
a second oxide structure; and
a second nitride structure overlying the second oxide structure;
a third portion of the metal nitride layer overlies a top surface of the first nitride structure; and
a fourth portion of the metal nitride layer overlies a top surface of the second nitride structure.

8. A semiconductor device, comprising:
a metal layer;
a gyroscope comprising a getter structure overlying the metal layer, wherein the getter structure comprises titanium; and
an accelerometer comprising an outgassing structure overlying the metal layer.

9. The semiconductor device of claim 8, wherein:
the outgassing structure comprises silicon oxide.

10. The semiconductor device of claim 8, wherein:
the getter structure is exposed to a vacuum sealed space.

11. The semiconductor device of claim 8, wherein:
the gyroscope comprises a bump stop structure overlying the metal layer.

12. The semiconductor device of claim 11, wherein the bump stop structure comprises:
a first dielectric structure;
a second dielectric structure, wherein a sidewall of the first dielectric structure faces and is spaced apart from a sidewall of the second dielectric structure; and
a metal nitride layer comprising:
a first portion aligned with the sidewall of the first dielectric structure; and
a second portion aligned with the sidewall of the second dielectric structure.

13. The semiconductor device of claim 12, wherein:
the first portion of the metal nitride layer is spaced apart from the second portion of the metal nitride layer.

14. The semiconductor device of claim 12, wherein:
the metal nitride layer comprises titanium nitride.

15. A method for forming a semiconductor device, comprising:
forming a titanium layer over a metal layer;
forming a metal nitride layer over the titanium layer;
forming one or more dielectric layers over the metal nitride layer; and
removing a portion of the one or more dielectric layers and a portion of the metal nitride layer to expose a portion, of the titanium layer, corresponding to a getter structure of a gyroscope.

16. The method of claim 15, wherein forming the titanium layer comprises:
forming the titanium layer such that a thickness of the titanium layer is larger than a thickness of the metal nitride layer.

17. The method of claim 15, wherein forming the metal nitride layer comprises:
forming the metal nitride layer to comprise titanium nitride.

18. The method of claim 15, comprising:
forming a trench through the one or more dielectric layers, the metal nitride layer, and the titanium layer; and
forming a second metal nitride layer in the trench.

19. The method of claim 18, wherein forming the second metal nitride layer comprises:
forming the second metal nitride layer to comprise titanium nitride.

20. The method of claim 15, wherein forming the one or more dielectric layers comprises:
performing high density plasma (HDP) chemical vapor deposition (CVD) to form an oxide layer over the metal nitride layer; and
forming a nitride layer over the oxide layer.
